(19) United States
(12) Patent Application Publication
(10) Pub. No.: US 2025/0338387 A1
(43) Pub. Date: Oct. 30, 2025

(54) SYSTEMS AND METHODS FOR COOLING AN APPARATUS HAVING BACKSIDE POWER DELIVERY COMPONENTS

(71) Applicant: Advanced Micro Devices, Inc., Santa Clara, CA (US)

(72) Inventors: Girish Anant Kini, Austin, TX (US); Edgar Stone, Austin, TX (US); Salvador D. Jimenez III, Austin, TX (US); Mark Steinke, Austin, TX (US); Ahmed Mohamed Abou-Alfotouh, Santa Clara, CA (US); Shardul Suresh Adkar, Austin, TX (US)

(73) Assignee: Advanced Micro Devices, Inc., Santa Clara, CA (US)

(21) Appl. No.: 18/162,666

(22) Filed: Jan. 31, 2023

(51) Int. Cl. H05K 1/02; H05K 7/20

(52) U.S. Cl. CPC H05K 1/0203; H05K 7/20254; H05K 2201/064

(57) ABSTRACT

The described apparatus can include a printed circuit board having a first side that includes an integrated circuit and a second side that is opposite the first side and that includes one or more power delivery components. The apparatus can additionally include a cooling system positioned to cool the one or more power delivery components located on the second side of the printed circuit board. Various other methods and systems are also disclosed.

### BACKGROUND

An integrated circuit or monolithic integrated circuit (e.g., an IC, a chip, or a microchip) is a set of electronic circuits on one small flat piece (e.g., chip) of semiconductor material, usually silicon. Integrated circuits can be implemented in various forms, such as expansion cards (e.g., graphics accelerator cards).

In computing, an expansion card (e.g., an expansion board, adapter card, peripheral card, or accessory card) is a printed circuit board that can be inserted into an electrical connector, or expansion slot (e.g., bus slot) on a computer's motherboard (e.g., backplane) to add functionality to a computer system. Sometimes the design of the computer's case and motherboard involves placing most or all of these slots onto a separate, removable card. Typically, such cards are referred to as riser cards in part because they project upward from the board and allow expansion cards to be placed above and parallel to the motherboard. Various standards define requirements for expansion cards, including power delivery requirements and form factors. One such standard corresponds to open compute project (OCP) accelerator module (OAM) for graphics accelerator cards.

A graphics card (e.g., video card, display card, graphics adapter, VGA card/VGA, video adapter, display adapter, or graphics processing unit (GPU)) is a computer expansion card that can generate a feed of graphics output to a display device such as a monitor. Graphics cards are sometimes called discrete or dedicated graphics cards to emphasize their distinction from an integrated graphics processor on the motherboard or the central processing unit (CPU). A GPU that performs the necessary computations is the main component in a graphics card.

Most graphics cards are not limited to simple display output. The GPU can be used for additional processing, which reduces the load from the CPU. Additionally, some computing platforms allow using graphics cards for general-purpose computing. Applications of general-purpose computing on graphics cards include artificial intelligence (AI) training, cryptocurrency mining, and molecular simulation. An AI accelerator is a class of specialized hardware accelerator or computer system designed to accelerate artificial intelligence and machine learning applications, including artificial neural networks and machine vision.

Usually, a graphics card comes in the form of a printed circuit board (e.g., expansion board) which can be inserted into an expansion slot. Others can have dedicated enclosures, and they can be connected to the computer via a docking station or a cable. These are known as external GPUs (eGPUs). Graphics cards are often preferred over integrated graphics for increased performance.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for cooling an apparatus having backside power delivery components.

FIG. 2 is a block diagram of an example apparatus having backside power delivery components and cooling systems.

FIG. 3 is a rising view of an example graphics accelerator card having backside power delivery components and cooling systems.

FIG. 4 is an exploded view of the example graphics accelerator card of FIG. 3.

FIG. 5 is an inverted exploded view of the example graphics accelerator card of FIG. 3.

FIG. 6 is a perspective view of example graphics accelerator cards having different fluid routing components.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for cooling an apparatus having backside power delivery components. It has become extremely challenging to meet the power delivery, and consequently the thermal requirements, on some expansion cards (e.g., graphics accelerator cards) due to the limited availability of printed circuit board (PCB) real estate for voltage regulators. The available PCB real estate for voltage regulators, primarily on the topside of the card, sets the upper limit of the amount of power that can be delivered to the integrated circuit (e.g., application specific integrated circuit (ASIC), such as an accelerator).

The disclosed systems and methods can address these challenges in part by placing power delivery components (PDCs) (e.g., voltage regulators) on the back side of a printed circuit board (PCB) having an integrated circuit (e.g., ASIC) and additional PDCs on a front side of the PCB. The disclosed systems and methods can further address these challenges by positioning a cooling system to cool the one or more power delivery components located on the back side of the printed circuit board. The disclosed systems and methods can further address these challenges by using a low profile cooling system that allows a combination of the cooling system and the backside PDCs to fit within open compute project (OCP) accelerator module (OAM) form factors (e.g., eight millimeters of clearance on the back side of the PCB).

Placing highly integrated voltage regulators and an associated cooling system on the backside of the expansion card (e.g., graphics accelerator card), underneath the integrated circuit (e.g., ASIC), enables increasing total power delivered to an integrated circuit (e.g., ASIC, such as an accelerator) to at least 1200 Watts, which yields a 33% increase compared to current graphics accelerator cards, and a 20% increase beyond power delivery goals of developing standards. Apart from increase in the power density, the disclosed systems and methods provide much lower power path resistance and power delivery network (PDN) impedance between the power delivery components (e.g., voltage regulators) and the ASIC (e.g., graphics processing unit (GPU)). This improvement increases the power conversion efficiency, and hence achieves higher throughput power. The disclosed systems and methods also reduce the PDN noise.

In one example, an apparatus includes a printed circuit board having a first side that includes an integrated circuit and a second side that is opposite the first side and that includes one or more power delivery components, and a cooling system positioned to cool the one or more power delivery components located on the second side of the printed circuit board.

Another example can be the previously described apparatus, wherein the first side of the printed circuit board has one or more additional power delivery components, and the apparatus further includes an additional cooling system positioned to cool the integrated circuit and the one or more additional power delivery components located on the first side of the printed circuit board.

Another example can be any of the previously described apparatuses, wherein the cooling system includes a first cold plate, and the additional cooling system includes a second cold plate.

Another example can be any of the previously described apparatuses, wherein the cooling system and the additional cooling system include one or more fluid routing components configured to provide fluid to the first cold plate and the second cold plate.

Another example can be any of the previously described apparatuses, wherein the one or more fluid routing components are configured to provide the fluid in parallel to the first cold plate and the second cold plate.

Another example can be any of the previously described apparatuses, wherein the one or more fluid routing components are configured to provide the fluid in series to the first cold plate and the second cold plate.

Another example can be any of the previously described apparatuses, wherein a combined power delivery of the one or more additional power delivery components located on the first side of the printed circuit board and the one or more power delivery components located on the second side of the printed circuit board is at least twelve-hundred watts.

Another example can be any of the previously described apparatuses, wherein a combined thickness of the cooling system, the one or more power delivery components, and a thermal interface material positioned between a cooling element of the cooling system and the one or more power delivery components is no greater than eight millimeters.

In one example, a cooling system includes a cooling element, a mechanical stiffener configured to hold the cooling element in position to cool one or more power delivery components located on a side of a printed circuit board opposite an additional side of the printed circuit board on which an integrated circuit is located, and a thermal interface material positioned between the cooling element and the one or more power delivery components.

Another example can be the previously described cooling system, wherein the cooling element corresponds to a cold plate.

Another example can be any of the previously described cooling systems, further including one or more fluid routing components configured to provide fluid to the cold plate.

Another example can be any of the previously described cooling systems, wherein the one or more fluid routing components are configured to provide the fluid in parallel to the cold plate and to an additional cold plate positioned to cool the application specific integrated circuit.

Another example can be any of the previously described cooling systems, wherein the one or more fluid routing components are configured to provide the fluid in series to the cold plate and to an additional cold plate positioned to cool the application specific integrated circuit.

Another example can be any of the previously described cooling systems, wherein a combined thickness of the cooling element, the one or more power delivery components, and the thermal interface material is no greater than eight millimeters.

Another example can be any of the previously described cooling systems, wherein a combined power delivery of the one or more power delivery components and one or more additional power delivery components located on the additional side of the printed circuit board is at least twelve-hundred watts.

Another example can be any of the previously described cooling systems, further including an additional cooling element, an additional mechanical stiffener configured to hold the additional cooling element in position to cool one or more additional power delivery components located on the additional side of the printed circuit board, and an additional thermal interface material positioned between the additional cooling element and the one or more additional power delivery components.

In one example, a method includes providing a printed circuit board having a first side that includes an integrated circuit and a second side that is opposite the first side and that includes one or more power delivery components and positioning a cooling system to cool the one or more power delivery components located on the second side of the printed circuit board.

Another example can be the previously described method, wherein the first side of the printed circuit board includes one or more additional power delivery components, and the method further includes positioning an additional cooling system to cool the integrated circuit and the one or more additional power delivery components located on the first side of the printed circuit board.

Another example can be any of the previously described methods, wherein the cooling system includes a first cold plate, and the additional cooling system includes a second cold plate.

Another example can be any of the previously described methods, wherein the cooling system and the additional cooling system include one or more fluid routing components configured to provide fluid to the first cold plate and the second cold plate.

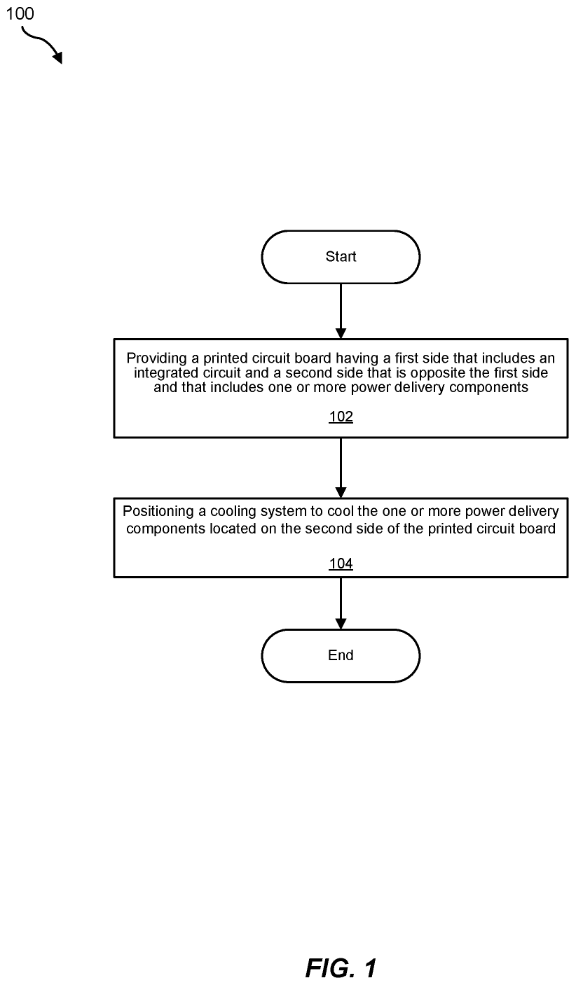

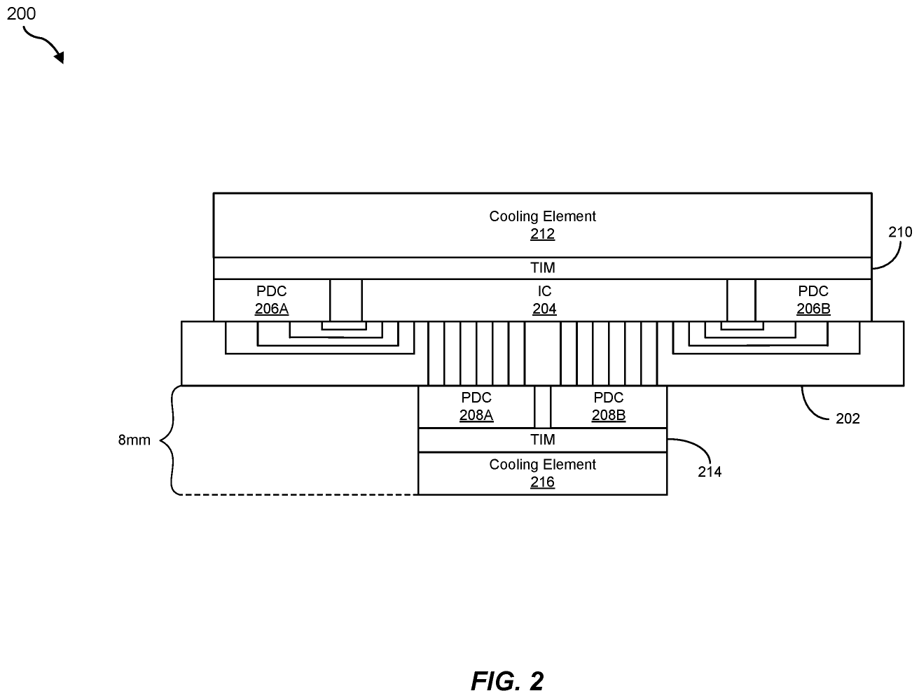

The following will provide, with reference to FIG. 1, detailed descriptions of example methods for cooling an apparatus having backside power delivery components. In addition, detailed descriptions of example apparatuses having backside power delivery components and cooling systems will be provided in connection with FIGS. 2-6.

FIG. 1 is a flow diagram of an example method 100 for cooling an integrated circuit having backside power delivery components. Each of the steps shown in FIG. 1 can represent multiple sub-steps, examples of which will be provided in greater detail below.

As illustrated in FIG. 1, at step 102 one or more of the systems described herein can provide a printed circuit board. For example, step 102 can include providing a printed circuit board having a first side that includes an integrated circuit and a second side that is opposite the first side and that includes one or more power delivery components.

The term “printed circuit board,” as used herein, can generally refer to a medium used in electrical and electronic engineering to connect electronic components to one another in a controlled manner. For example, and without limitation, a printed circuit board (PCB) can take the form of a laminated sandwich structure of conductive and insulating layers, with each of the conductive layers being designed with an artwork pattern of traces, planes, and other features (e.g., like wires on a flat surface) etched from one or more sheet layers of copper laminated onto and/or between sheet layers of a non-conductive substrate. Electrical components can be fixed to conductive pads on the outer layers in the shape designed to accept the component's terminals, generally by means of soldering, to both electrically connect and mechanically fasten them to it. Another manufacturing process can add vias, such as plated-through holes that allow interconnections between layers. PCBs can be single-sided (e.g., one copper layer), double-sided (e.g., two copper layers on both sides of one substrate layer), or multi-layer (e.g., outer and inner layers of copper, alternating with layers of substrate). Multi-layer PCBs allow for much higher component density because circuit traces on the inner layers would otherwise take up surface space between components.

The term “integrated circuit,” as used herein, can generally refer to a set of electronic circuits on one small flat piece (e.g., chip) of semiconductor material, usually silicon. For example, and without limitation, integrated circuits can correspond to central processing units (CPUs), field programmable gate arrays (FPGAs), and expansion cards (e.g., graphics accelerator cards).

The term “application specific integrated circuit,” as used herein, can generally refer to an integrated circuit (IC) chip customized for a particular use, rather than intended for general-purpose use. For example, and without limitation, ASICs can include AI accelerators, graphics accelerators, graphics processing units, etc. However, as noted above, some computing platforms allow using graphics cards for general-purpose computing. Thus, while an ASIC is not necessarily intended for use as a general purpose processor, an ASIC can nevertheless be capable of providing such functionality.

The term “power delivery components,” as used herein, can generally refer to an electricity regulation device. For example, and without limitation, power delivery component can refer to one or more voltage regulators. A voltage regulator is a system designed to automatically maintain a constant voltage. A voltage regulator can use a simple feed-forward design or include negative feedback. It can use an electromechanical mechanism or electronic components. Depending on the design, it can be used to regulate one or more alternating current (AC) or direct current (DC) voltages.

Step 102 can be performed in a variety of ways. In one example, a combined power delivery of the one or more power delivery components located on the second side of the printed circuit board and one or more additional power delivery components located on the first side of the printed circuit board can be at least twelve-hundred watts.

At step 104, one or more of the systems described herein can position a cooling system. For example, step 104 can include positioning a cooling system to cool the one or more power delivery components located on the second side of the printed circuit board.

The term “cooling system,” as used herein, can generally refer to passive or active systems that are designed to regulate and dissipate the heat generated by a computer to maintain optimal performance and protect the computer from damage that will occur from overheating. For example, and without limitation, example cooling systems include one or more cold plates and/or one or more heat pipes. Cooling systems can also include thermal interface material that goes into joints to fill air gaps between solid surfaces during assembly. Thermal interface material can correspond to, be combined with, and/or include one or more heat spreaders that have high thermal conductivity and can be used as a bridge between a heat source and a heat exchanger.

Step 104 can be performed in a variety of ways. In one example, the first side of the printed circuit board can include one or more additional power delivery components, and step 104 can include positioning an additional cooling system to cool the integrated circuit and the one or more additional power delivery components located on the first side of the printed circuit board. In some of these examples, the cooling system can include a first cold plate and the second cooling system can include a second cold plate. In some examples, the cooling system and the additional cooling system can include one or more fluid routing components directing fluid into and out of the first cold plate and the second cold plate. In some examples, the one or more fluid routing components are configured to provide the fluid in parallel to the first cold plate and the second cold plate. In other examples, the one or more fluid routing components are configured to provide the fluid in series to the first cold plate and the second cold plate. In some examples, the combined thickness of the cooling system, the one or more power delivery components, and a thermal interface material positioned between a cooling element of the cooling system and the one or more power delivery components is no greater than eight millimeters. In other examples, the cooling system can include a thinned heat pipe structure including an embedded heat pipe that emerges to an extended surface (e.g., a copper heat pipe and an aluminum plate).

Referring to FIG. 2, an example apparatus 200 has backside power delivery components (PDCs) 208A and 208B (e.g., voltage regulators) and cooling systems. A PCB 202 has an integrated circuit (IC) 204 (e.g., ASIC) on a front (e.g., top) side along with front side power delivery components (PDCs) 206A and 206B (e.g., voltage regulators) located adjacent to (e.g., on one or more sides of) the IC 204. The IC 204 and/or the front side PDCs 206A and 206B can be cooled by a front side cooling system that includes a cooling element 212 (e.g., cold plate and/or heat pipe) and thermal interface material 214 located between the cooling element 210 and the IC 204 and/or PDCs 206A and 206B. The backside PDCs 208A and 208B are located on a back (e.g., bottom) side of the PCB 202 beneath the IC 204, and lines of a power delivery network (PDN) can extend into the PCB 202 (e.g., silicon) and extend between the IC 204 and the PDCs 206A, 206B, 208A, and 208B. Due to the location of the back side PDCs 208A and 208B, the lines of the PDN that extend between the IC 204 and the back side PDCs 208A and 208B can be shorter than the lines of the PDN that extend between the IC 204 and the front side PDCs 206A and 206B.

The shorter lines of the PDN that extend between the IC 204 and the back side PDCs 208A and 208B yield numerous benefits. For example, the shorter lines result in reduced PCB copper planes and a reduced number of layers for reduced PCB cost. Also, the shorter lines result in reduced power path resistance between the PDCs 208A and 208B and the IC 204 for reduced PCB copper losses. Also, the shorter lines result in reduced PDN impedance from the PDCs 208A and 208B to the IC 204. Further, the shorter lines result in reduced PDN noise and increased conversion efficiency for increased useful throughput power. In some examples, the PDCs 206A, 206B, 208A, and 208B can, in combination, provide a combined power delivery of at least twelve-hundred watts.

A challenge in implementing the apparatus 200 having the features described above arises in cooling the back side PDCs 208A and 208B. No known cooling system exists that can achieve this goal while fitting within the eight millimeters of clearance available beneath the PCB 202 in an open compute project (OCP) accelerator module (OAM), especially where the PDCs 208A and 208B already consume approximately three millimeters of the available clearance. However, a cooling element 216 (e.g., cold plate and/or heat pipe) that is no more than four millimeters thick so that it can be implemented beneath the PDCs 208A and 208B, with a no more than one-half millimeter thick thermal interface material 214 located between the cooling element 216 and the PDCs 208A and 208B. Compared to using a heat pipe, using a cold plate as the cooling element 216 has the additional benefit of fitting within open compute OAM form factors.

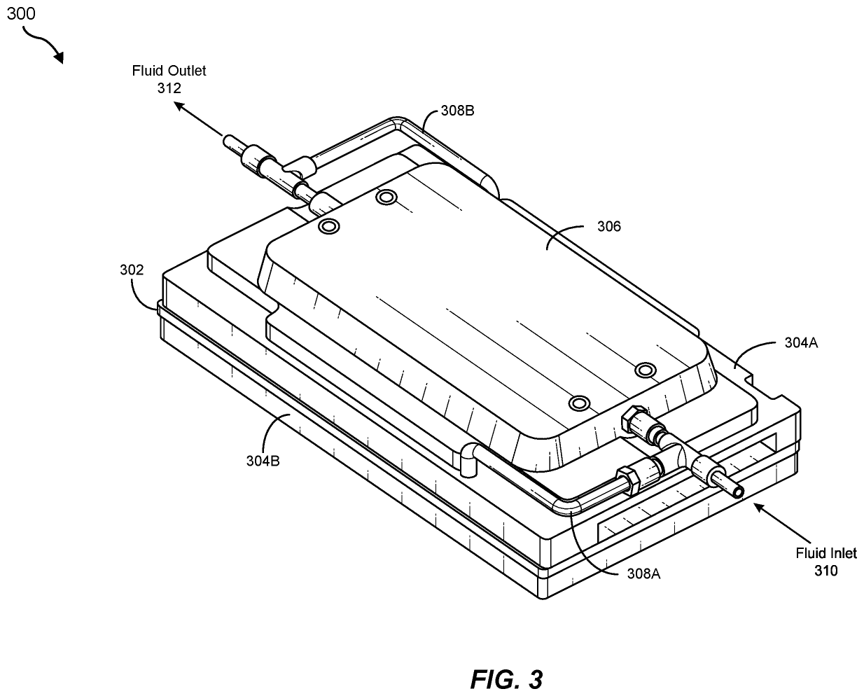

Referring to FIG. 3, an example graphics accelerator card 300 having backside power delivery components and cooling systems includes a liquid-cooled cold plate and a thermal interface material in contact with a highly integrated power delivery component. This high-density, high-performance, and highly integrated power delivery and cooling system meets the ever-increasing power demand from AI accelerators. The example graphics accelerator card 300 includes two separate cooling solutions, one on the top for cooling the ASIC and the other below the PCB 302 to cool the power delivery components. This structure creates a sandwich between two cold plates, providing rigidity to the OAM card and improving reliability and providing resistance to shock and random vibration.

As shown in FIG. 3, the example graphics accelerator card 300 having backside power delivery components and cooling systems has a PCB 302 and mechanical stiffeners 304A and 304B that surround their respective cold plates and hold them in respective positions to cool front side components (e.g., ASIC and front side PDCs) and the backside PDCs. For example, mechanical stiffener 304A can hold front side cold plate 306 in position to cool the ASIC. In some examples, mechanical stiffener 304A can further hold front side cold plate 306 in position to cool the front side PDCs. Alternatively or additionally, mechanical stiffener 304A can be vented (e.g. on one or more sides) to allow cooling (e.g., further cooling) of the front side PCBs by convection and/or to provide electrical access to the front side PCBs and or the ASIC. Example graphics accelerator card 300 can further have fluid routing components 308A and 308B (e.g., tubes) with a fluid inlet 310 that facilitates introduction of cooling fluid to one or more of the cold plates and a fluid outlet 312 that facilitates egress of cooling fluid from the one or more cold plates.

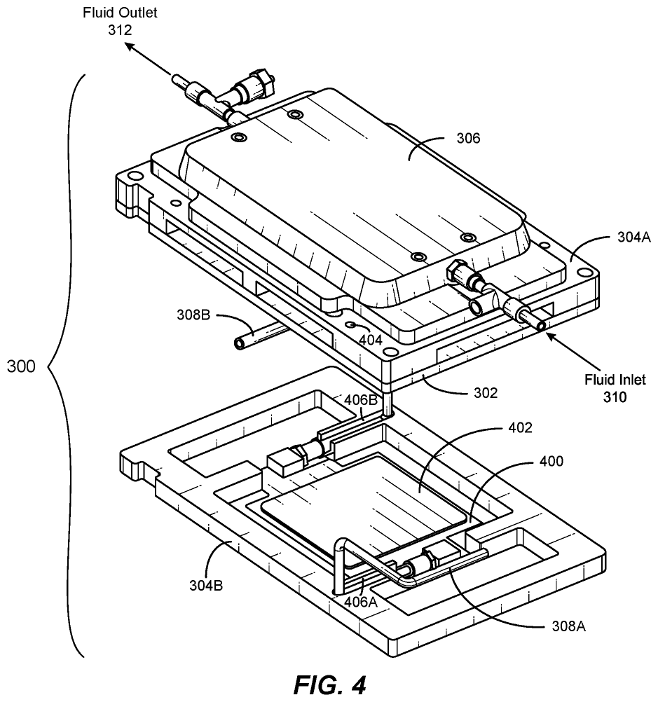

Referring to FIG. 4, an exploded view of the example graphics accelerator card 300 illustrates components of the example graphics accelerator card 300 in greater detail. For example, PCB 302, mechanical stiffeners 304A and 304B, front side cold plate 306, fluid routing components 308A and 308B, fluid inlet 310, and fluid outlet 312 are arranged as shown. Additionally, example graphics accelerator card 300 includes a back side cold plate 400 and a thermal interface material 402 located on the back side cold plate 400. Back side cold plate 400 can have various internal cooling fluid path configurations (e.g., cooling channels, pin fins, serpentine channels, etc.). Further, mechanical stiffener 304A can have one or more apertures 404 (e.g., through holes) that permit one or more of fluid routing components 308A and 308B to extend through the mechanical stiffener 304A and direct cooling fluid from the front side of the PCB 302 to the back side of the PCB 302 and/or from the back side of the PCB 302 to the front side of the PCB 302. Still further, mechanical stiffener 304B can have one or more channels 406A and 406B that permit one or more of fluid routing components 308A and 308B to extend into the mechanical stiffener 304B and direct cooling fluid into and/or out of back side cold plate 400. Finally, mechanical stiffener 304B can be vented (e.g., on a bottom thereof) in a manner that provides further cooling of the back side PCBs by convection and/or that permits electrical access to the back side PCBs.

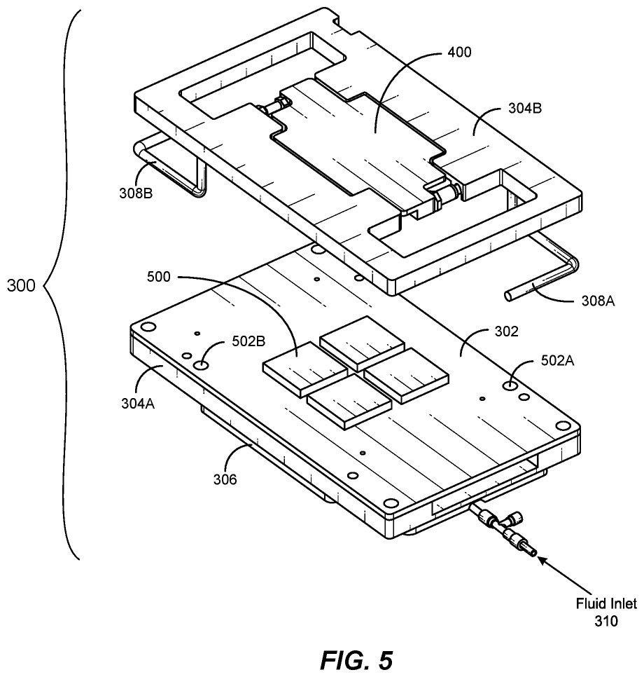

Referring to FIG. 5, an inverted exploded view of the example graphics accelerator card 300 illustrates further components of the example graphics accelerator card 300 in greater detail. For example, PCB 302, mechanical stiffeners 304A and 304B, front side cold plate 306, back side cold plate 400, fluid routing components 308A and 308B, and fluid inlet 310 are arranged as shown. Additionally, example graphics accelerator card 300 includes back side PDCs 500 (e.g., voltage regulators) located on a back side of the PCB 302. When mechanical stiffener 304B is joined to the back side of PCB 302, it positions back side cold plate 400 to cool the back side PDCs 500. One or more apertures 502A and 502B (e.g., through holes) in the PCB 302 can permit one or more of fluid routing components 308A and 308B to extend through the PCB 302 and direct fluid from the front side of the PCB 302 to the back side of the PCB 302 and/or from the back side of the PCB 302 to the front side of the PCB 302.

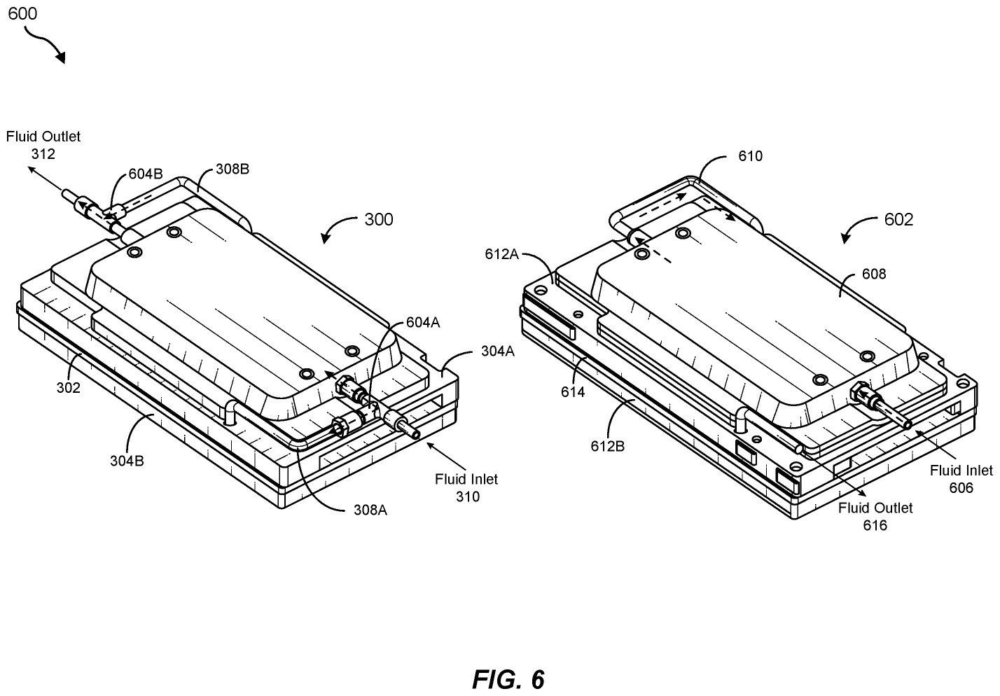

Referring to FIG. 6, example graphics accelerator cards having different configurations of fluid routing components 600 are shown. For example, graphics accelerator card 300 has T-splitters 604A and 604B that divide a cooling fluid routing path in a manner that accomplishes parallel delivery and removal of cooling fluid to and from the front side cold plate and the backside cold plate. For example, fluid routing component 308A can extend from T-splitter 604A through mechanical stiffener 304A and the PCB 302 into mechanical stiffener 304B and introduce fluid to the back side cold plate. Similarly, fluid routing component 308B can extend from the back side cold plate through mechanical stiffener 304B, the PCB 302, and mechanical stiffener 304A to T-splitter 604B to allow egress of cooling fluid from the back side cold plate. When cooling fluid enters fluid inlet 310, it passes into T-splitter 604A from which it is directed in parallel into the front side cold plate and the back side cold plate. The cooling fluid then exits the two cold plates and is directed to T-splitter 604B, from which it exits through fluid outlet 312.

In contrast to example graphics accelerator card 300, example graphics accelerator card 602 implements a cooling fluid routing path in a manner that accomplishes serial delivery of cooling fluid to the front side cold plate and extraction of the cooling fluid from the backside cold plate. For example, fluid inlet 606 can introduce cooling fluid to the front side cold plate 608 and fluid routing component 610 can direct cooling fluid that exits the front side cold plate 608 through mechanical stiffener 612A and PCB 614 into mechanical stiffener 612B and the back side cold plate. Similarly, fluid outlet 616 can extend from the back side cold plate through mechanical stiffener 612B, the PCB 614, and mechanical stiffener 612A and allow egress of the cooling fluid.

Numerous variations to the fluid routing configurations are possible. For example, the top side cooling plate and bottom side cooling plate can have separate fluid routing systems with two fluid inlets and two fluid outlets. Additionally, serial fluid delivery can be performed in a manner that first delivers the cooling fluid to the bottom side cold plate and then to the top side cold plate (e.g., by reversing the fluid flow direction for example graphics accelerator card 602). Also, the fluid routing can be accomplished using channels formed in the PCB and/or mechanical stiffeners with gaskets or seals between layers (e.g., reduced tubes or no tubes). Further, the mechanical stiffeners can be formed as one piece. Still further, some implementations can accomplish fluid delivery without passing through the PCB by causing the PCB layer to be absent in a region surrounding the fluid path. Finally, many other variations will be readily apparent to the skilled person.

As set forth above, placing highly integrated voltage regulators and an associated cooling system on the backside of an integrated circuit (e.g., CPU, FPGA, expansion card, graphics accelerator card, etc.), underneath the integrated circuit, increases total power delivery to the integrated circuit (e.g., ASIC, such as a graphics accelerator) to at least 1200 Watts. Apart from increase in the power density, the disclosed systems and methods provide significantly reduced power path resistance and power delivery network (PDN) impedance between the back side voltage regulators and the front side integrated circuit. This reduced power path resistance and reduced PDN impedance increases the power conversion efficiency, and hence achieves higher throughput power while reducing the PDN noise. The low profile backside cooling system can cool the backside power delivery components without departing from form factors specified by industry standards.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

1. An apparatus, comprising:
a printed circuit board having:
a first side that includes an integrated circuit; and
a second side that is opposite the first side and that includes two or more power delivery components; and
a cooling system that includes a cold plate positioned on the two or more power delivery components located on the second side of the printed circuit board.

2. The apparatus of claim 1, wherein the first side of the printed circuit board has one or more additional power delivery components, and the apparatus further comprises:
an additional cooling system positioned to cool the integrated circuit and the one or more additional power delivery components located on the first side of the printed circuit board.

3. The apparatus of claim 2, wherein the cooling system includes a first cold plate, and the additional cooling system includes a second cold plate.

4. The apparatus of claim 3, wherein the cooling system and the additional cooling system include one or more fluid routing components configured to provide fluid to the first cold plate and the second cold plate.

5. The apparatus of claim 4, wherein the one or more fluid routing components are configured to provide the fluid in parallel to the first cold plate and the second cold plate.

6. The apparatus of claim 5, wherein the one or more fluid routing components are configured to provide the fluid in series to the first cold plate and the second cold plate.

7. The apparatus of claim 2, wherein a combined power delivery of the one or more additional power delivery components located on the first side of the printed circuit board and the two or more power delivery components located on the second side of the printed circuit board is at least twelve-hundred watts.

8. The apparatus of claim 1, wherein a combined thickness of the cold plate, the two or more power delivery components, and a thermal interface material positioned between the cold plate and the two or more power delivery components is no greater than eight millimeters.

9. A cooling system comprising:
a cold plate;
a mechanical stiffener configured to hold the cold plate on two or more power delivery components located on a side of a printed circuit board opposite an additional side of the printed circuit board on which an integrated circuit is located; and
a thermal interface material positioned between the cold plate and the two or more power delivery components.

10. The cooling system of claim 9, wherein the cold plate has a thickness no greater than four millimeters.

11. The cooling system of claim 10, further comprising one or more fluid routing components configured to provide fluid to the cold plate.

12. The cooling system of claim 11, wherein the one or more fluid routing components are configured to provide the fluid in parallel to the cold plate and to an additional cold plate positioned to cool the integrated circuit.

13. The cooling system of claim 11, wherein the one or more fluid routing components are configured to provide the fluid in series to the cold plate and to an additional cold plate positioned to cool the integrated circuit.

14. The cooling system of claim 9, wherein a combined thickness of the cold plate, the two or more power delivery components, and the thermal interface material is no greater than eight millimeters.

15. The cooling system of claim 9, wherein a combined power delivery of the two or more power delivery components and one or more additional power delivery components located on the additional side of the printed circuit board is at least twelve-hundred watts.

16. The cooling system of claim 9, further comprising:
an additional cooling element;
an additional mechanical stiffener configured to hold the additional cooling element in position to cool one or more additional power delivery components located on the additional side of the printed circuit board; and
an additional thermal interface material positioned between the additional cooling element and the one or more additional power delivery components.

17. A method comprising:
providing a printed circuit board having:
a first side that includes an integrated circuit; and
a second side that is opposite the first side and that includes two or more power delivery components; and
positioning a first cold plate on the two or more power delivery components located on the second side of the printed circuit board.

18. The method of claim 17, wherein the first side of the printed circuit board includes one or more additional power delivery components, and the method further comprises:
positioning a second cold plate to cool the integrated circuit and the one or more additional power delivery components located on the first side of the printed circuit board.

19. The method of claim 18, wherein the first cold plate has a thickness no greater than four millimeters.

20. The method of claim 19, further comprising:
configuring one or more fluid routing components to provide fluid to the first cold plate and the second cold plate.
